(19) United States
(12) Patent Application Publication
(10) Pub. No.: US 2021/0004101 A1
(43) Pub. Date: Jan. 7, 2021

(54) Touch Display Panel, Flexible Display Apparatus, and Method for Manufacturing Touch Display Panel

(71) Applicant: Huawei Technologies Co., Ltd., Shenzhen (CN)

(72) Inventors: Shanshan Wei, Shanghai (CN); Yanfeng Liang, Shanghai (CN); Jianhui Li, Dongguan (CN); Haohui Long, Beijing (CN)

(21) Appl. No.: 16/766,587

(22) PCT Filed: Nov. 24, 2017
(86) PCT No.: PCT/CN2017/112912

§ 371 Date: May 22, 2020

(51) Int. Cl. G06F 3/041; G06F 1/16

(52) U.S. Cl. CPC G06F 3/0412; G06F 2203/04102; G06F 1/1652

(57) ABSTRACT

This application provides a touch display panel, a flexible display apparatus, and a method for manufacturing the touch display panel. The touch display panel includes a flexible substrate, a display component, a touch component, and a thin film encapsulation layer. The touch component and the display component are located at different locations on an upper surface of the flexible substrate, and the touch component and the display component are stacked together through folding, to form the touch display panel. The thin film encapsulation layer is formed on an upper surface of the touch component, an upper surface of the display component, and the upper surface of the flexible substrate. Due to a bendable feature of the flexible substrate, the display component and the touch component are manufactured at different locations on the flexible substrate at the same time, and an integrated touch display panel is formed through folding. In this way, a procedure of separately manufacturing the touch component is saved, and corresponding manufacturing costs are reduced. In addition, because the touch component and the display component are interconnected by using an internal circuit, a procedure of electrically connecting the touch component to the display component during assembly is saved. This shortens a manufacturing procedure and reduces costs of the touch display panel.

### TECHNICAL FIELD

This application relates to display technologies, and in particular, to a touch display panel, a flexible display apparatus, and a method for manufacturing the touch display panel.

### BACKGROUND

As display technologies develop, flexible display technologies are increasingly widely applied. A flexible display apparatus is made of a soft material, and is deformable and bendable. A common flexible display apparatus is a flexible organic light emitting diode (Organic Light Emitting Diode. OLED) display apparatus. An OLED is widely applied because of advantages such as self-luminescence, a wide viewing angle, an almost infinitely high contrast, relatively low power consumption, and a very fast reaction speed.

FIG. 1 is a schematic structural diagram of an existing flexible OLED display apparatus. As shown in FIG. 1, the flexible OLED display apparatus includes, sequentially from bottom to top, a copper foil (Cu foil), a foam (Foam), an active organic light emitting diode (Active Matrix Organic Light Emitting Diode, AMOLED) panel (panel), a thin film encapsulation (Thin Film Encapsulation, TFE) layer, a touch panel (Touch panel), a polarizer (Polarizer, POL), a solid optically clear adhesive (Optically Clear Adhesive, OCA), and cover glass (Cover Glass, CG). A signal cable of the touch panel and a signal cable of the AMOLED panel are integrated and then connected to an integrated circuit (integrated circuit, IC) chip in a _film on film (Film on film, FOF) manner. The IC chip has a touch and display function. After passing through the IC chip, an FOF connector is connected to a flexible printed circuit (Flexible Printed Circuit, FPC) by using a transfer FOF connector, and the FOF connector is connected to the FPC by using a boarder-to-boarder (Boarder to boarder) connector.

For the flexible OLED display apparatus in the prior art, the AMOLED touch panel, TFE, the touch panel, and the like need to be sequentially stacked on a same substrate (the AMOLED touch panel in FIG. 1 includes a substrate, and the substrate is not separately shown). For the entire apparatus, a manufacturing procedure is relatively long, a manufacturing process is complex, and costs are high.

### SUMMARY

This application provides a touch display panel, a flexible display apparatus, and a method for manufacturing the touch display panel, to shorten a manufacturing procedure and reduce costs of a display apparatus.

According to a first aspect of this application, a touch display panel is provided, and the touch display panel includes:

a flexible substrate, a display component, a touch component, and a thin film encapsulation layer.

The touch component and the display component are located at different locations on an upper surface of the flexible substrate. The touch component and the display component are stacked together through folding, to form the touch display panel. The thin film encapsulation layer is formed on an upper surface of the touch component, an upper surface of the display component, and the upper surface of the flexible substrate.

Optionally, the touch component includes a receive end and a transmit end. The receive end and the transmit end are located at different locations on the upper surface of the flexible substrate, and the receive end and the transmit end are separately folded above the display component.

Optionally, the receive end, the transmit end, and the display component are stacked, and two adjacent layers between the receive end, the transmit end, and the display component are bonded by using an optically clear adhesive.

Optionally, the receive end and the transmit end are located on two sides of the display component.

Optionally, the receive end and the transmit end are located side by side on one side of the display component.

Optionally, the touch component includes a receive end and a transmit end. The receive end and the transmit end are formed at a same location on a surface of the flexible substrate, the receive end and the transmit end are disposed in a stacked manner, and the receive end and the transmit end are folded as a whole above the display component.

Optionally, two adjacent layers between the receive end, the transmit end, and the display component are bonded by using an optically clear adhesive.

Optionally, a signal cable of the display component and a signal cable of the touch component are routed out in an integrated manner and then electrically connected to an external circuit.

According to a second aspect of this application, a flexible display apparatus is provided, and the flexible display apparatus includes any touch display panel provided in the first aspect of this application, a polarizer, and a cover. The polarizer is disposed on an upper surface of the touch display panel, and the cover is disposed above the polarizer.

Optionally, the touch display panel is connected to the external circuit in a chip on film COF manner, or the touch display panel is connected to the external circuit in a chip on plastic COP manner.

Optionally, the touch display panel is connected to the external circuit by using a COF connector, and a through hole is disposed at a location at which the touch display panel is connected to the COF connector.

Alternatively, the touch display panel is connected to the external circuit by using a COP connector, and a through hole is disposed at a location at which the touch display panel is connected to the COP connector.

Optionally, the flexible display apparatus further includes a foam and a copper foil. The foam is located on a lower surface of the touch display panel, and the copper foil is located on a lower surface of the foam.

According to a third aspect of this application, a method for manufacturing a touch display panel is provided, and the method includes:

manufacturing a display component and a touch component at different locations on an upper surface of a flexible substrate;

performing thin film encapsulation on the flexible substrate, the display component, and the touch component to form a touch display component;

cutting the touch display component into a minimum foldable unit; and

folding and then stacking the touch component and the display component in the foldable unit to form the touch display panel.

Optionally, the touch component includes a receive end and a transmit end, and the manufacturing a display component and a touch component at different locations on an upper surface of a flexible substrate includes:

manufacturing the receive end, the transmit end, and the display component at different locations on the upper surface of the flexible substrate; and

the folding and then stacking the touch component and the display component in the foldable unit to form the touch display panel includes:

folding the receive end and the transmit end above the display component.

Optionally, the receive end and the transmit end are located on two sides of the display component.

Optionally, the receive end and the transmit end are located side by side on one side of the display component.

Optionally, the touch component includes a receive end and a transmit end, and the manufacturing a display component and a touch component at different locations on an upper surface of a flexible substrate includes:

manufacturing the receive end and the transmit end at a first location on the upper surface of the flexible substrate, and manufacturing the display component at a second location on the flexible substrate, where the receive end and the transmit end are disposed in a stacked manner; and

the folding and then stacking the touch component and the display component in the foldable unit to form the touch display panel includes:

folding the receive end and the transmit end as a whole above the display component.

This application provides the touch display panel, the flexible display apparatus, and the method for manufacturing the touch display panel. The touch display panel includes the flexible substrate, the display component, the touch component, and the thin film encapsulation layer. The touch component and the display component are located at different locations on the upper surface of the flexible substrate, and the touch component and the display component are stacked together through folding, to form the touch display panel. The thin film encapsulation layer is formed on the upper surface of the touch component, the upper surface of the display component, and the upper surface of the flexible substrate. Due to a bendable feature of the flexible substrate, the display component and the touch component are manufactured at different locations on the flexible substrate at the same time, and an integrated touch display panel is formed through folding. In this way, a procedure of separately manufacturing the touch component is saved, and corresponding manufacturing costs are reduced. In addition, because the touch component and the display component are interconnected by using an internal circuit, a procedure of electrically connecting the touch component to the display component during assembly is saved. This shortens a manufacturing procedure and reduces costs of the touch display panel.

### BRIEF DESCRIPTION OF DRAWINGS

FIG. 1 is a schematic structural diagram of an existing flexible OILED display apparatus;

FIG. 2 is a schematic diagram of a touch display panel before folding;

FIG. 3 is a schematic diagram of a status change of the touch display panel shown in FIG. 2 in a folding process;

FIG. 4 is another schematic diagram of a touch display panel before folding;

FIG. 5 is still another schematic diagram of a touch display panel before folding;

FIG. 6 is a sectional view of a touch display panel after thin film encapsulation;

FIG. 7 is a schematic diagram of an A-A′ cross section of a flexible display apparatus;

FIG. 8 is a schematic diagram of a B-B′ cross section of the flexible display apparatus shown in FIG. 7;

FIG. 9 is a schematic diagram of an A-A′ cross section of another flexible display apparatus;

FIG. 10 is a schematic diagram of a B-B′ cross section of the flexible display apparatus shown in FIG. 9;

FIG. 11 is a schematic diagram in which a touch display panel is connected to an external circuit in a COF manner;

FIG. 12 is a schematic diagram in which a touch display panel is connected to an external circuit in a COP manner;

FIG. 13 is a flowchart of a method for manufacturing a touch display panel; and

FIG. 14 is a flowchart of a method for manufacturing a flexible display apparatus.

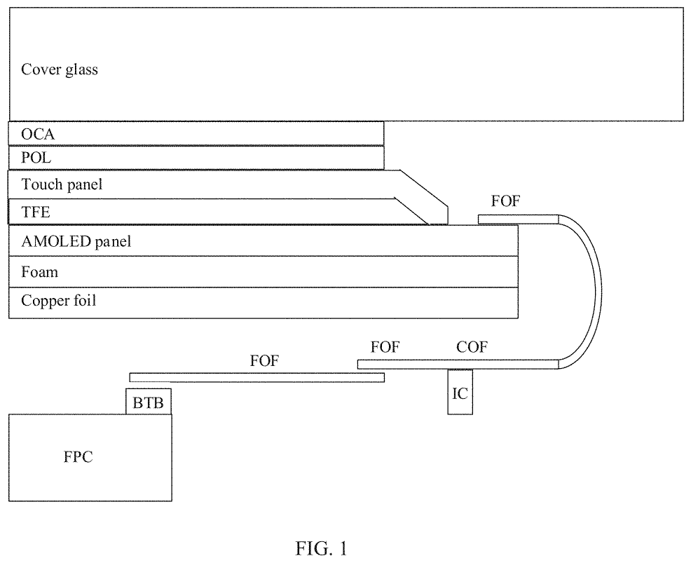

### DESCRIPTION OF EMBODIMENTS

This application provides a touch display panel. The touch display panel includes a flexible substrate, a display component, a touch component, and a thin film encapsulation TFE layer. The touch component and the display component are located at different locations on an upper surface of the flexible substrate, and the touch component and the display component are stacked together through folding, to form the touch display panel. The TFE layer is formed on an upper surface of the touch component, an upper surface of the display component, and the upper surface of the flexible substrate.

Because the flexible substrate is bendable, the display component and the touch component are manufactured at different locations on the flexible substrate, and an integrated touch display panel is formed through folding. During folding, a part that is of the flexible substrate and that is located below the touch component is folded above the display component. In this way, a procedure of separately manufacturing the touch component is saved, and corresponding manufacturing costs are reduced. In addition, because the touch component and the display component are interconnected by using an internal circuit, a procedure of electrically connecting the touch component to the display component during assembly is saved. This shortens a manufacturing procedure and reduces costs of a flexible display panel.

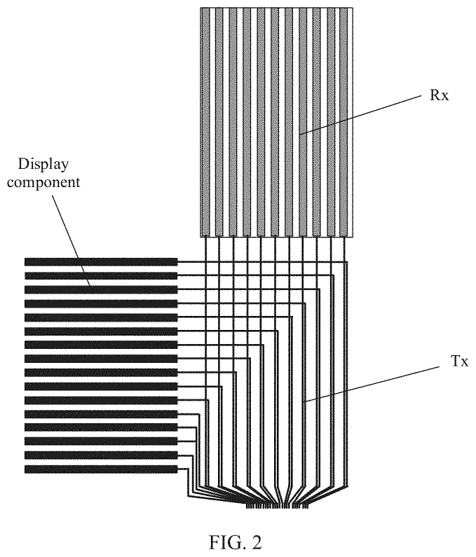

FIG. 2 is a schematic diagram of a touch display panel before folding. As shown in FIG. 2, a touch component includes a receive end Rx and a transmit end Tx, The receive end Rx and the transmit end Tx are located at different locations on an upper surface of a flexible substrate, and the receive end Rx and the transmit end Tx are separately folded above a display component. Specifically, the receive end Rx, the transmit end Tx, and the display component are stacked, and two adjacent layers between the receive end Rx, the transmit end Tx, and the display component are bonded by using an optically clear adhesive OCA. After folding, the receive end Rx may be located above the transmit end Tx, or the receive end Rx may be located below the transmit end Tx.

In this embodiment, a signal cable of the display component and a signal cable of the touch component may be routed out in an integrated manner and then electrically connected to an external circuit, and the signal cable of the touch component includes a signal cable of the receive end Rx and a signal cable of the transmit end Tx. That the signal cable of the display component and the signal cable of the touch component are routed out in an integrated manner means that: The signal cable of the display component and the signal cable of the touch component are aggregated into one cable, only one interface needs to be provided externally, and a connection needs to be performed once only in a subsequent external connection process. As shown in FIG. 2, the signal cable of the receive end Rx, the signal cable of the transmit end Tx, and the signal cable of the display component are aggregated to one side of the display component. Certainly, the signal cable of the receive end Rx, the signal cable of the transmit end Tx, and the signal cable of the display component may alternatively be aggregated to one side of the receive end Rx, or aggregated to one side of the transmit end Tx.

It may be understood that the signal cable of the receive end Rx and the signal cable of the transmit end Tx may just pass through an area of the display component. However, the receive end Rx and the transmit end Tx are not electrically connected to the display component, and the receive end Rx and the transmit end Tx are not interconnected. Optionally, the receive end Rx and the transmit end Tx may share or partially share some cables with the display component. For example, the receive end Rx, the transmit end TX, and the display component share a grounding end.

A location of the receive end Rx and that of the transmit end Tx are not limited in this embodiment of this application. In a manner, the receive end Rx and the transmit end Tx are located on two sides of the display component. In another manner, the receive end Rx and the transmit end Tx are located side by side on one side of the display component.

When the receive end Rx and the transmit end Tx are located on two sides of the display component, the receive end Rx and the transmit end Tx may be located on two adjacent sides of the display component, or may be located on two non-adjacent sides (namely, two sides opposite to each other) of the display component. As shown in FIG. 2, the receive end Rx, the transmit end Tx, and the display component are all located on the upper surface of the flexible substrate. The receive end Rx is located above the display component, and the transmit end Tx is located on a left side of the display component.

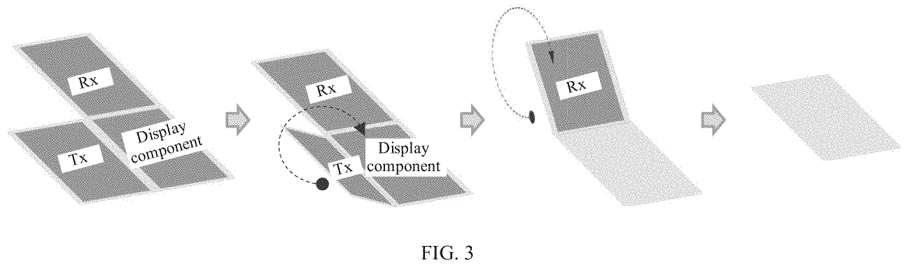

Optionally, an area of the receive end Rx, an area of the transmit end Tx, and an area of the display component are the same or approximately the same, and the area of the receive end Rx is the same as the area of the transmit end Tx. FIG. 3 is a schematic diagram of a status change of the touch display panel shown in FIG. 2 in a folding process. As shown in FIG. 3, the transmit end Tx is first folded upward to be located above the display component, the transmit end Tx covers the display component, and the transmit end Tx is bonded to the display component by using an OCA. Then the receive end Rx is folded upward to be located above the transmit end Tx, the receive end Rx covers the transmit end Tx, and the receive end Rx is bonded to the transmit end Tx by using an OCA. In this way, a stacked touch display panel is formed.

To form a touch display panel on which the receive end Rx is located above the display component and the transmit end Tx is located above the receive end Rx, correspondingly, during folding, the receive end Rx is first folded upward to be located above the display component, and the receive end Rx is bonded to the display component by using an OCA; and then the transmit end Tx is folded upward to be located above the receive end Rx, and the transmit end Tx is bonded to the receive end by using an OCA.

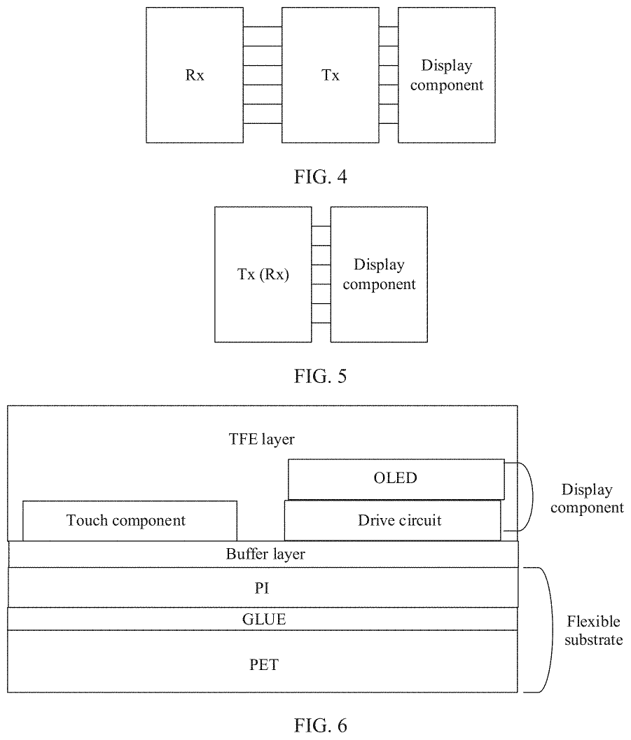

FIG. 4 is another schematic diagram of a touch display panel before folding. As shown in FIG. 4, a receive end Rx and a transmit end Tx are located side by side on a left side of a display component. During folding, the receive end Rx may be first folded above the transmit end Tx, and the receive end Rx is bonded to the transmit end Tx by using an OCA. Then the receive end Rx and the transmit end Tx are folded as a whole above the display component, and the receive end Rx is bonded to the display component by using an OCA. Alternatively, the transmit end Tx may be first folded above the display component, and then the receive end Rx is folded above the transmit end Tx. For the touch display panel shown in FIG. 4, different structures are formed based on different folding orders. In the former folding manner, the receive end Rx is located above the display component, and the transmit end Tx is located above the receive end Rx. In the latter folding manner, the transmit end Tx is located above the display component, and the receive end Rx is located above the transmit end Tx.

In the touch display panel shown in FIG. 4, the receive end Rx and the transmit end Tx are sequentially located side by side on the left side of the display component. Certainly, the receive end Rx and the transmit end Tx may alternatively be sequentially located side by side on an upper side, a lower side, or a right side of the display component. It may be understood that a sequence of the transmit end Tx and the receive end Rx is not limited in this embodiment. Alternatively, the transmit end Tx and the receive end Rx may be sequentially located side by side on one side of the display component.

In the touch display panel shown in each of FIG. 2 and FIG. 4, the receive end Rx and the transmit end Tx are located at different locations on the flexible substrate, and folding needs to be performed twice to form the stacked touch display panel.

In another implementation of this application, the receive end Rx and the transmit end Tx are formed at a same location of the flexible substrate. The receive end Rx and the transmit end Tx are disposed in a stacked manner, and the receive end Rx and the transmit end Tx are folded as a whole above the display component. The receive end Rx and the transmit end Tx may be connected by using an OCA. FIG. 5 is still another schematic diagram of a touch display panel before folding. Referring to FIG. 5, a receive end Rx and a transmit end Tx are first manufactured at a same location on an upper surface of a flexible substrate. The receive end Rx may be located above the transmit end Tx, and the receive end Rx may alternatively be located below the transmit end Tx.

In the touch display panel shown in FIG. 5, the receive end Rx and the transmit end Tx are located as a Whole on any side of a display component. During folding, the receive end Rx and the transmit end Tx are folded as a whole above the display component. After folding, the receive end Rx or the transmit end Tx is adjacent to the display component, and the receive end Rx or the transmit end Tx is bonded to the display component by using an OCA. In this manner, the receive end Rx and the transmit end Tx are manufactured at a same location of the flexible substrate, to reduce an area of the flexible substrate. In addition, a folding procedure is required to be performed once only, and a procedure is further reduced.

Optionally, the flexible substrate includes a polyethylene terephthalate (Polyethylene terephthalate, PET) layer, a glue (GLUE) layer, and a polyimide (Polyimide, PI) layer. The PET layer is located at a bottom layer of the flexible substrate, the PI layer and the PET layer are bonded by using glue, and the PET layer is mainly used to reinforce a structure of the Pi layer. Herein, only an example is used for description. A structure of the flexible substrate is not limited to the foregoing structure provided that the flexible substrate is foldable.

Optionally, before the display component and a touch component are manufactured on the flexible substrate, a buffer layer further needs to be manufactured. Alternatively, a flexible substrate with a buffer layer may be used. The buffer layer may prevent a metal ion (aluminum, barium, sodium, and the like) in PI from spreading to the display component during a thermal process. The display component may be an AMOLED, and the AMOLED includes an OLED and a drive circuit. The display component may alternatively include a Micro LED and a drive circuit.

The OLED may include an anode layer, a cathode layer, and a light emitting layer formed between the anode layer and the cathode layer. The light emitting layer is made of an organic light emitting material. A light emitting principle of the OLED is: Driven by an electric field, an organic semiconductor material and a light emitting material emit light through carrier injection and composition. For example, the OLED usually uses an ITO pixel electrode as an anode layer of a component and uses a metal electrode as a cathode layer of the component. Under a specific drive voltage, an electron is injected from a cathode into an electron transport layer, and a hole is injected from an anode into a hole transport layer. The electron reaches the light emitting layer after passing through the electron transport layer, and the hole also reaches the light emitting layer after passing through the hole transport layer. The electron meets with the hole at the light emitting layer to form an excitor and make a light emitting molecule excited. The light emitting molecule emits visible light after radiation relaxation.

The Micro LED is obtained after a light emitting diode (Light Emitting Diode, LED) structure is designed to be thin, micro, and arrayed. A size of the Micro LED is only about 1 μm to 10 μm, and the Micro LED is a self-luminous display technology with a wide color gamut, high brightness, a long life, fast response and low power consumption. Both the OLED and the Micro LED are self-luminous, while a difference is that the OLED emits light by using an organic material, and the Micro LED emits light by using an inorganic material.

The drive circuit may be low temperature polysilicon (Low Temperature Polysilicon, LTPS), amorphous silicon (Amorphous Silicon, a-Si), indium gallium zinc oxide (Indium Gallium Zinc Oxide, IGZO), or the like. An LTPS drive circuit is used as an example. If the LTPS is directly made on the PI, the metal ion (aluminum, barium, sodium, and the like) may spread to an active area of the LTPS during the thermal process. Quality of a back surface of polysilicon may be improved based on a thickness of the buffer layer or a deposition condition. In this case, heat conduction can be reduced, and a cooling rate of silicon heated by laser is slowed down, so as to facilitate crystallization of the silicon.

A process of manufacturing the touch component, the drive circuit, the OLED, or the Micro LED on the flexible substrate is relatively mature, and there are many process changes. A detailed process is not described herein.

For example, the display component is the AMOLED. In the prior art, the drive circuit and the OLED need to be first manufactured on the flexible substrate to form the display component, then thin film encapsulation is performed on the display component, and the touch component is further manufactured and overlaid on a thin film. As a result, a procedure is relatively long.

Different from the prior art, in this application, the drive circuit and the touch component are manufactured at different locations on a same flexible substrate in a manner, the drive circuit and the touch component a manufactured at the same time, and the OLED is further manufactured after the drive circuit is manufactured. In another manner, the drive circuit is first manufactured, then the OLED is further manufactured after the drive circuit is manufactured, and the touch component is manufactured during manufacturing of the OLED. Compared with the prior art, a procedure of separately manufacturing the touch component is saved, corresponding manufacturing costs are reduced, and a procedure of electrically connecting the touch component to the display component is saved.

Because the organic material is easy to react with water and oxygen, a flexible display apparatus using the OLED requires high on encapsulation. In this embodiment, Ether the touch component and the display component are manufactured on the flexible substrate, the TFE is performed. FIG. 6 is a sectional view of a touch display panel after thin film encapsulation. As shown in FIG. 6, a flexible substrate includes a PI layer, a GLUE layer, and a PET layer. A buffer layer is located above the PI layer, a touch component and a display component are located at different locations on an upper surface of the buffer layer, and the display component includes an OLED and a drive circuit. The drive circuit is located on the upper surface of the buffer layer, and the OLED is located on an upper surface of the drive circuit. A TFE layer is formed on an upper surface of the touch display panel before folding. In other words, the entire TFE layer covers the touch component, the display component, and the flexible substrate (or the buffer layer), to prevent water and oxygen from entering the display component and the touch component, and protect the touch display panel.

This application further provides a flexible display apparatus, including any one of the foregoing touch display panels, a polarizer POL, and a cover. The POL is disposed on an upper surface of the touch display panel, and the cover is disposed above the POL. The POL is configured to prevent external light from being reflected outside the touch display panel, and the cover may be bonded to the POL by using an OCA. The cover may be made of glass or another transparent material, and the cover is used to protect the touch display panel.

Optionally, the flexible display apparatus further includes a foam and a copper foil. The foam is located on a lower surface of the touch display panel, and the copper foil is located on a lower surface of the foam. The foam is mainly used to protect the flexible display apparatus. The copper foil has the following functions: electromagnetic shielding prevention, heat dissipation, cushion and protection, and grounding. For the electromagnetic shielding prevention, the copper foil prevents interference between another electromagnetic signal of a device and a display and touch signal. For the heat dissipation, the copper foil can quickly transfer heat of a high-temperature local part of the touch display panel to an entire surface. For the cushion and protection, the copper foil prevents a housing of the device from damaging, such as squeezing and crushing, a back of the touch display panel. For the grounding, the copper foil is used as a grounding electrode of the display component, a grounding electrode of the touch component, or a grounding electrode of the housing.

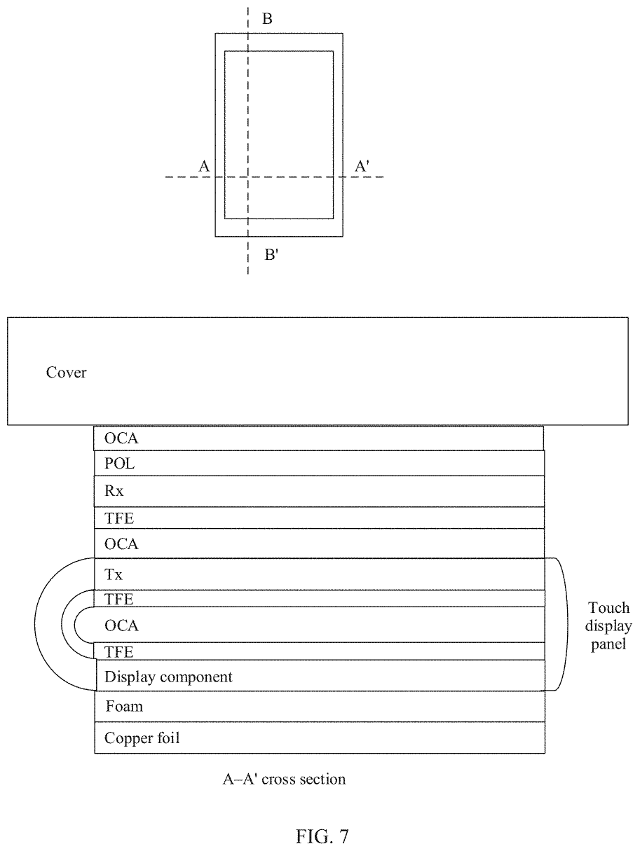

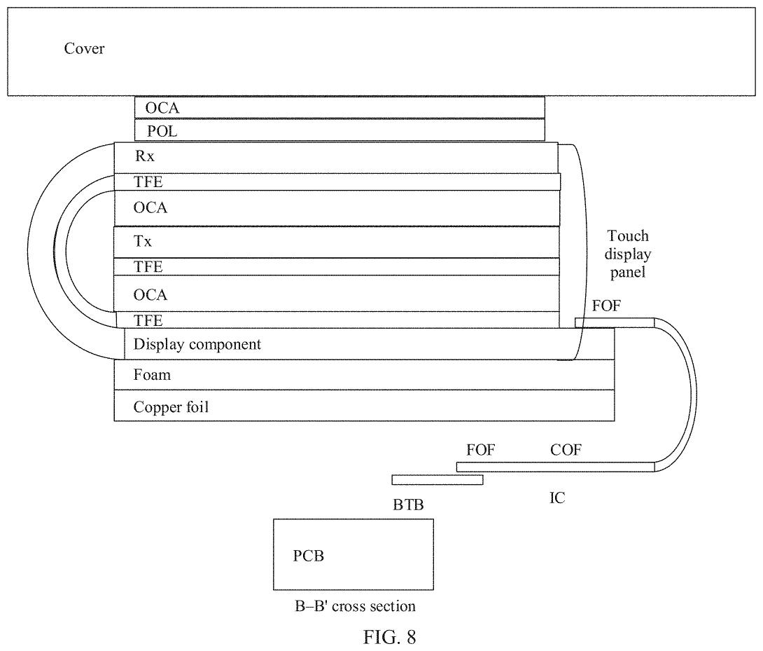

FIG. 7 is a schematic diagram of an A-A′ cross section of a flexible display apparatus, and FIG. 8 is a schematic diagram of a B-B′ cross section of the flexible display apparatus shown in FIG. 7. Referring to FIG. 7 and FIG. 8, the flexible display apparatus includes, sequentially from bottom to top, a copper foil, a foam, a touch display panel, a POI and a cover. The touch display panel in this embodiment may be formed through folding by using the touch display panels shown in FIG. 2 and FIG. 4, and the flexible display apparatus shown in FIG. 7 and FIG. 8 can be formed after folding is performed twice.

It should be noted that, the touch display panel shown in FIG. 7 and FIG. 8 includes only a receive end Rx, a transmit end Tx, a display component, and a TFE layer. A flexible substrate is not shown, but it does not mean that the touch display panel does not include the flexible substrate. When the touch display panel is being folded, the receive end Rx and the transmit end Tx are folded as a whole with the flexible substrate. It may be considered that the flexible substrate is integrated with the receive end Rx, the transmit end Tx, and the display component as a whole. In addition, in FIG. 7 and FIG. 8, the receive end. Rx is located above the transmit end ix, and this is merely an example for description herein. In actual application, the receive end Rx may alternatively be located below the transmit end ix,

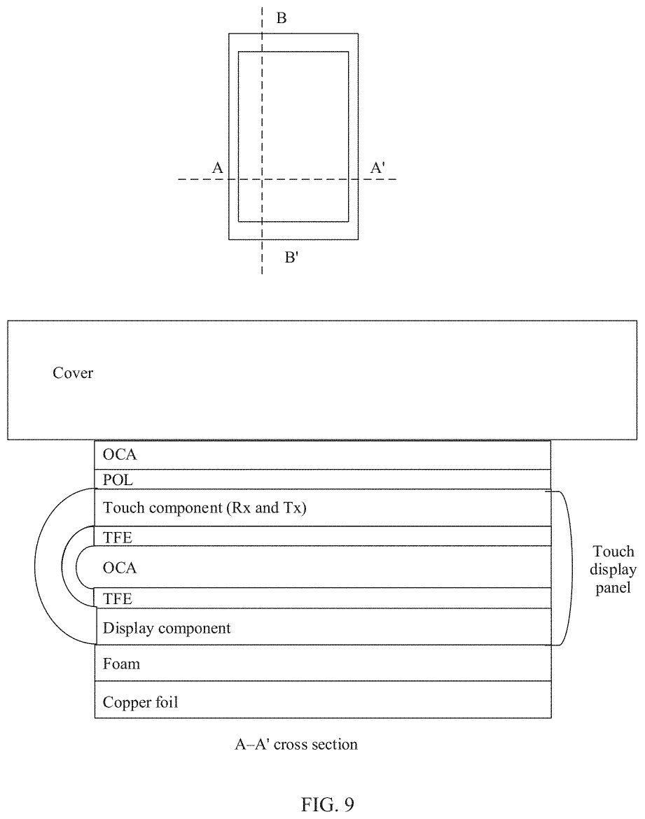

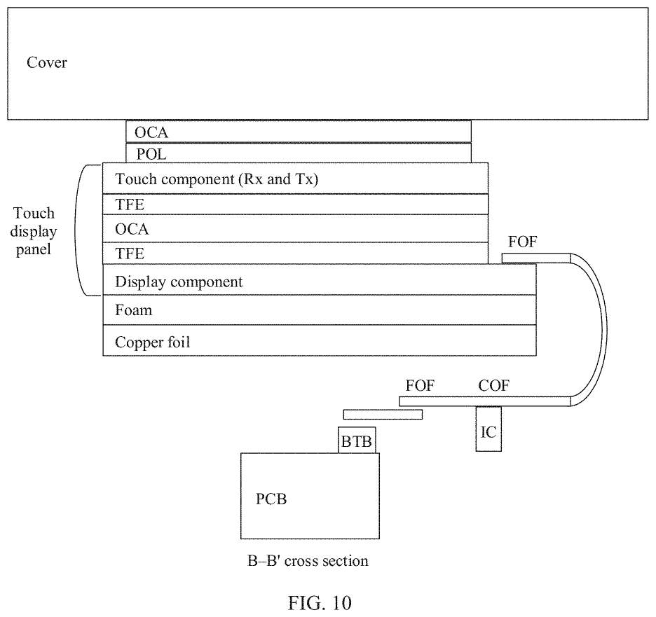

FIG. 9 is a schematic diagram of an A-A′ cross section of another flexible display apparatus, and FIG. 10 is a schematic diagram of a B-B′ cross section of the flexible display apparatus shown in FIG. 9. Referring to FIG. 9 and FIG. 10, the flexible display apparatus includes, sequentially from bottom to top, a copper foil, a foam, a touch display panel, a POL, and a cover The touch display panel in this embodiment may be formed through folding by using the touch display panel shown in FIG. 5, and the flexible display apparatus shown in FIG. 9 and FIG. 10 is formed after folding is performed once. It should be noted that, in the touch display panel shown in FIG. 9, a receive end Rx may be located above a transmit end Tx, and the receive end Rx may alternatively be located below the transmit end Tx. At a bent location, a display component is electrically connected to a touch component. A flexible substrate is also not shown in the flexible display apparatus shown in FIG. 9 and FIG. 10.

The flexible display apparatus needs to be connected to another circuit in a terminal device. Specifically, the touch display panel of the flexible display apparatus is connected to an external circuit. In an implementation, the touch display panel is connected to the external circuit in a chip on film (Chip on film, or Chip On Film, COF for short) manner. In another implementation, the touch display panel is connected to the external circuit in a chip on plastic (Chip on plastic, or Chip On Panel, COP for short) manner.

The COF, also referred to as a chip-on-flex, usually refers to a soft film construction technology in which a chip is fastened to a grain on a flexible printed circuit board by using an Au-Sn eutectic thermal compression technology or an anisotropic conductive film (Anisotropic Conductive Film, ACF) thermal compression technology, and is a technology in which a soft additional circuit board (which may be referred to as a COF connector) is used as a packaged chip carrier to connect the chip and a soft substrate circuit.

The COP, also referred to as a flip chip flexible panel, usually refers to a panel construction technology in which a chip is fastened to a grain on a flexible panel by using the Au-Sn eutectic thermal compression technology or the ACF thermal compression technology, and is a technology in which the flexible panel (which may be referred to as a COP connector) is used as a packaged chip carrier on which the chip is connected to a flexible panel circuit.

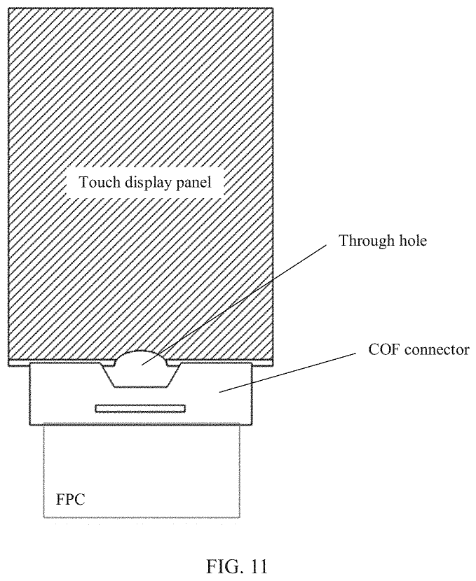

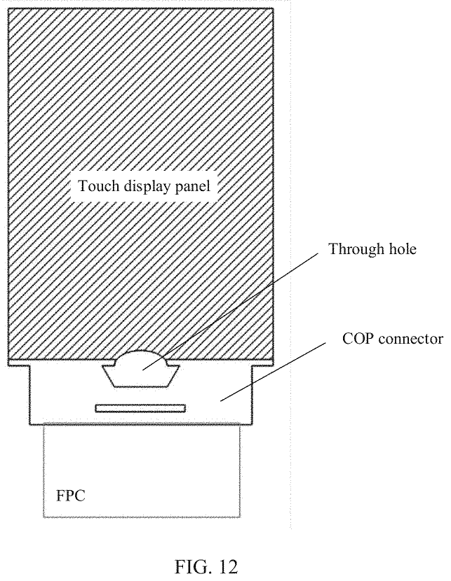

FIG. 11 is a schematic diagram in which a touch display panel is connected to an external circuit in a COF manner. As shown in FIG. 11, the touch display panel is connected to an FPC by using a COF connector. The COF connector is made of a soft material and may be bent to a back of the touch display panel, and the COF connector may be connected to the touch display panel through a thermal compression process. Optionally, a through hole is disposed at a location at which the touch display panel is connected to the COF connector, and a camera or various sensors may be disposed in the through hole. A shape of the through hole is not limited in this application. As shown in FIG. 11, a side that is of the through hole and that is located on the touch display panel is in a semicircular shape, and a side that is of the through hole and that is located on the COF connector is in a trapezoid shape. The shape of the through hole may correspond to a shape of the camera or a shape of the sensor. Usually, only one edge of the touch display panel is connected to the COF connector, and the through hole may alternatively be disposed on another edge that is of the touch display panel and that is not connected to the COF connector. For example, the through hole is disposed on an edge that is of the touch display panel and that is opposite to the COF connector. This is not limited in this embodiment.

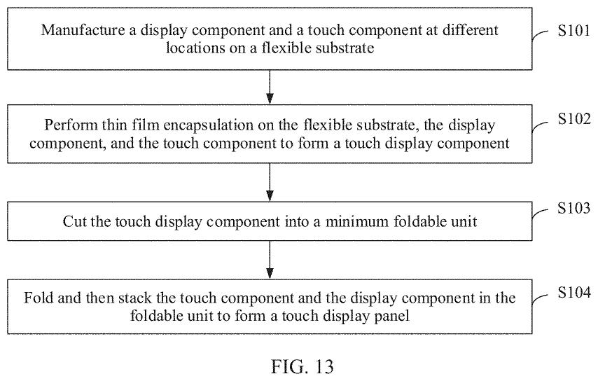

FIG. 12 is a schematic diagram in which a touch display panel is connected to an external circuit in a COP manner. As shown in FIG. 12, in this manner, the touch display panel needs to be extended. To be specific, a signal cable (including a signal cable of a touch component and that of a display component) on the touch display panel is integrated into an exposed COP connector, and then an FPC is bound to the COP connector through a thermal compression process, to realize circuit integration and simplification and greatly reduce a quantity of routed-out cables. Optionally, a through hole is disposed at a location at which the touch display panel is connected to the COP connector, and a camera or various sensors may be disposed in the through hole. A shape of the through hole is not limited in this application. As shown in FIG. 12, a side that is of the through hole and that is located on the touch display panel is in a semicircular shape, and a side that is of the through hole and that is located on the COP connector is in a trapezoid shape. The shape of the through hole may correspond to a shape of the camera or a shape of the sensor. Usually, only one edge of the touch display panel is connected to the COP connector, and the through hole may alternatively be disposed on another edge that is of the touch display panel and that is not connected to the COP connector. This is not limited in this embodiment.

According to the method in this embodiment, the signal cable of the display component and the signal cable of the touch component are routed out in an integrated manner, and a COF connection or a COP connection needs to be performed once only between the entire touch display panel and the external circuit. This reduces a connection procedure between the display component, the touch component, and the external circuit, and reduces corresponding electrical connection consumables.

The flexible display apparatus provided in the embodiments includes the touch display panel, the polarizer, and the cover. The touch display panel includes the flexible substrate, the display component, the touch component, and the TFE layer, The touch component and the display component are located at different locations on the upper surface of the flexible substrate. The TFE layer is formed on an upper surface of the touch component, an upper surface of the display component, and the upper surface of the flexible substrate. The touch component is formed above the display component through folding. The polarizer is located on the upper surface of the touch display panel, and the cover is located above the polarizer. Due to a bendable feature of the flexible substrate, the display component and the touch component are manufactured at different locations on a same flexible substrate, and an integrated touch display panel is formed through folding. In this way, a procedure of separately manufacturing the touch component is saved, and corresponding manufacturing costs are reduced. In addition, because the touch component and the display component are interconnected by using an internal circuit, a procedure of electrically connecting the touch component to the display component during assembly is saved. This shortens a manufacturing procedure and reduces costs of the flexible display apparatus.

This application further provides a method for manufacturing a touch display panel. The method for manufacturing a touch display panel provided in this embodiment may be applied to manufacture the foregoing touch display panel. FIG. 13 is a flowchart of the method for manufacturing a touch display panel. As shown in FIG. 13, the method for manufacturing a touch display panel includes the following steps.

Step S101: Manufacture a display component and a touch component at different locations on a flexible substrate.

The flexible substrate may include a buffer layer. If the flexible substrate does not include the buffer layer, optionally, the buffer layer may be first deposited on the flexible substrate, and then the display component and the touch component are manufactured. A specific manufacturing procedure may vary with different flexible substrates. For example, when the flexible substrate includes a PI layer, a GLUE layer, and a PET layer, that the display component and the touch component are manufactured at different locations on the flexible substrate includes the following steps.

Step 1: Deposit the buffer layer on a glass plate on which PI is coated.

The buffer layer may be deposited on the PI, for example, through

Chemical vapor deposition (Chemical Vapor Deposition, CVD). Because of high flatness of glass, an accurate exposure size may be obtained. Therefore, the glass is required. In addition, the glass has particular strength, which is convenient for water to flow automatically

Step 2: Manufacture the display component and the touch component at different locations of the buffer layer.

Because PET does not have many excellent features of the PI, for example, high temperature resistance, a drive circuit of the touch component and that of the display component cannot be directly manufactured on the flexible substrate. Currently, according to a common method, the PI is coated on the glass plate, and the drive circuit, an OLED or a Micro LED of the display component and the touch component are manufactured on the PI. In this process, there is a high temperature procedure with a temperature higher than 400 degrees.

The display component includes the drive circuit, the OLED, or the Micro LED. The OLED is used as an example. When the display component and the touch component are manufactured, in a manner, the drive circuit and the touch component are manufactured at the same time, and the OLED is further manufactured after the drive circuit is manufactured. In another manner, the drive circuit is first manufactured, then the OLED is further manufactured after the drive circuit is manufactured, and the touch component is manufactured during manufacturing of the OLED. Compared with the prior art, a procedure of separately manufacturing the touch component is saved, corresponding manufacturing costs are reduced, and a procedure of electrically connecting the touch component to the display component is saved.

The touch component includes a receive end Rx and a transmit end Tx. A manufacturing sequence of the receive end Rx and the transmit end Tx is not limited. During manufacturing, in a manner, the receive end Rx and the transmit end Tx are manufactured at a same location on an upper surface of the flexible substrate, and the receive end Rx and the transmit end Tx are disposed in a stacked manner. In another manner, the receive end Rx and the transmit end Tx are manufactured at different locations on the upper surface of the flexible substrate. Optionally, the receive end Rx and the transmit end Tx are located on two sides of the display component, or the receive end Rx and the transmit end Tx are located side by side on one side of the display component.

Step 3: Perform TEE, and transfer the PI and layers above the PI onto the PET to form a touch display component.

An entire TEE layer covers the touch component, the display component, and the flexible substrate (or the buffer layer). During transfer, the glass plate is removed, and the PI is bonded to the PET by using glue or another adhesive. The touch display component formed in this step needs to be cut into the touch display panel.

Step S102: Perform thin film encapsulation on the flexible substrate, the display component, and the touch component to form the touch display component.

Step S103: Cut the touch display component into a minimum foldable unit.

The foldable unit is a structure of the touch display panel before folding.

Step S104: Fold and then stack the touch component and the display component in the foldable unit to form the touch display panel.

When the receive end Rx and the transmit end Tx are located at different locations on the upper surface of the flexible substrate, the touch component and the display component in the foldable unit are folded and then stacked to form the touch display panel. Specifically, to separately fold the receive end Rx and the transmit end Tx above the display component, folding needs to be performed twice.

When the receive end Rx and the transmit end Tx are located at a same location on the upper surface of the flexible substrate, the touch component and the display component in the foldable unit are folded and then stacked to form the touch display panel. Specifically, to fold the receive end Rx and the transmit end Tx as a whole above the display component, folding needs to be performed once.

The method in this embodiment may be applied to manufacture the touch display panel provided in the foregoing embodiments. According to the method in this embodiment, the touch component and the display component may be manufactured on a flexible component at the same time. Compared with the prior art, the procedure of separately manufacturing the touch component is saved, corresponding manufacturing costs are reduced, and a procedure of electrically connecting the touch component to the display component is saved.

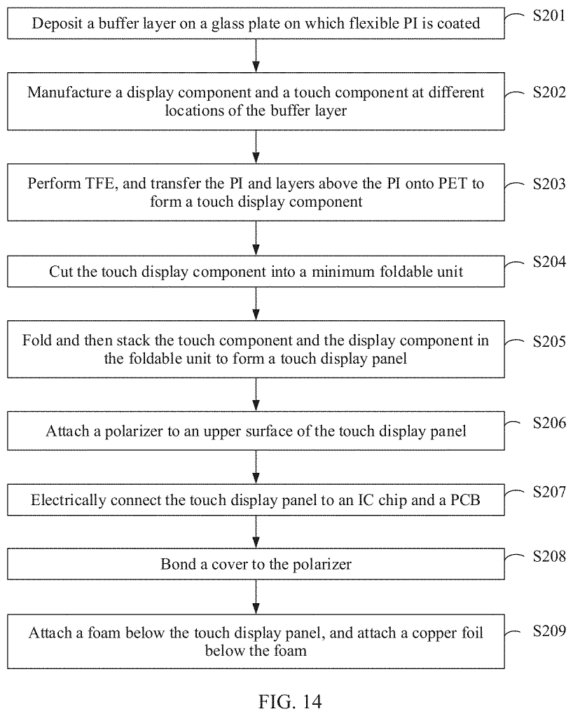

This application further provides a method for manufacturing a flexible display apparatus, applied to manufacture the foregoing flexible display apparatus. FIG. 14 is a flowchart of the method for manufacturing a flexible display apparatus. As shown in FIG. 14, the method provided in this embodiment includes the following steps.

Step S201: Deposit a buffer layer on a glass plate on which flexible PI is coated.

Step S202: Manufacture a display component and a touch component at different locations of the buffer layer.

Step S203: Perform TFE, and transfer the PI and layers above the PI onto PET to form a touch display component.

For a specific implementation of steps S201 to S203, refer to the description in the embodiment shown in FIG. 13. Details are not described herein again.

Step S204: Cut the touch display component into a minimum foldable unit.

The minimum foldable unit may be shown in FIG. 6.

Step S205: Fold and then stack the touch component and the display component in the foldable unit to form a touch display panel.

The touch component is bonded to the display component by using an OCA, and a receive end Rx of the touch component is also bonded to a transmit end Tx of the touch component by using the OCA.

Step S206: Attach a polarizer to an upper surface of the touch display panel.

Step S207: Electrically connect the touch display panel to an IC chip and a PCB,

A connection may be performed in a COF manner and a COP manner. For a specific connection manner, refer to the description in the foregoing embodiments. Details are not described herein again.

Step S208: Bond a cover to the polarizer.

Step S209: Attach a foam below the touch display panel, and attach a copper foil below the foam.

It is clear that, the person skilled in the art can make various modifications and variations to the embodiments of this application without departing from the spirit and scope of this application. This application is intended to cover these modifications and variations to the embodiments of this application provided that these modifications and variations fall within the scope of protection defined by the following claims and their equivalent technologies.

1. A touch display panel, comprising:
a flexible substrate comprising a flexible substrate upper surface;
a display component comprising a display component upper surface and coupled to a first location of the flexible substrate upper surface;
a touch component comprising a touch component upper surface and coupled to a second location of the flexible substrate upper surface; and
a thin film encapsulation layer disposed on the touch component upper surface, the display component upper surface, and the flexible substrate upper surface, wherein the display component and the touch component are folded together to form the touch display panel.

2. The touch display panel of claim 1, wherein the touch component further comprises:
a receive end located at a third location of the flexible substrate upper surface, and
a transmit end located at a fourth location of the flexible substrate upper surface, wherein the receive end and the transmit end are separately folded onto the display component.

3. The touch display panel of claim 2, wherein the receive end, the transmit end, and the display component are stacked, and wherein the receive end, the transmit end, and the display component are bonded using an optically clear adhesive.

4. The touch display panel of claim 2, wherein the display component further comprises a display component first side and a display component second side, wherein the receive end is located on the display component first side and the transmit end is located on the display component second side or wherein the receive end and the transmit end are located side-by-side on the display component first side.

5. (canceled)

6. The touch display panel of claim 1, wherein the touch component comprises:
a receive end; and
a transmit end, wherein the receive end and the transmit end are formed at a same location on the flexible substrate upper surface, wherein the receive end and the transmit end are disposed in a stacked manner, and wherein the receive end and the transmit end are folded on to the display component.

7. The touch display panel of claim 6, wherein layers between the receive end, the transmit end, and the display component are bonded using an optically clear adhesive.

8. The touch display panel of claim 1, wherein the display component further comprises a display component signal cable, wherein the touch component further comprises a touch component signal cable, and wherein the display component signal cable and the touch component signal cable are routed out in an integrated manner and configured to electrically couple to an external circuit.

9-12. (canceled)

13. A touch display panel manufacturing method, comprising:
manufacturing a display component at a first location of a flexible substrate upper surface;
manufacturing a touch component at a second location of the flexible substrate upper surface;
performing thin film encapsulation on a flexible substrate, the display component, and the touch component to form a touch display component;
cutting the touch display component into a minimum foldable unit; and
folding and stacking the touch component and the display component in the minimum foldable unit to form the touch display panel.

14. The touch display panel manufacturing method of claim 13, wherein the touch component comprises a receive end and a transmit end, and wherein the touch display panel manufacturing method further comprises:
manufacturing the receive end at a third location on the flexible substrate upper surface;
manufacturing the transmit end at a fourth location on the flexible substrate upper surface;
manufacturing the display component at a fifth location on the flexible substrate upper surface; and
folding the receive end and the transmit end onto the display component.

15. The touch display panel manufacturing method of claim 14, wherein the display component further comprises a display component first side and a display component second side, wherein the receive end is located on the display component first side and the transmit end are is located on the display component second side of the display component or wherein the receive end and the transmit end are located side-by-side on the display component first side.

16. (canceled)

17. The touch display panel manufacturing method of claim 13, wherein the touch component comprises a receive end and a transmit end, and the wherein the touch display pan& manufacturing method further comprises:
manufacturing the receive end and the transmit end at a third location on the flexible substrate upper surface;
manufacturing the display component at a fourth location on the flexible substrate upper surface, wherein the receive end and the transmit end are disposed in a stacked manner; and
folding the receive end and the transmit end onto the display component.

18. A mobile terminal, comprising:
a camera;
a sensor; and
a touch display panel, comprising:
a flexible substrate comprising a flexible substrate upper surface;
a display component comprising a display component upper surface and coupled to a first location of the flexible substrate upper surface;
a touch component comprising a touch component upper surface and coupled to a second location of the flexible substrate upper surface; and
a thin film encapsulation layer disposed on the touch component upper surface, the display component upper surface, and the flexible substrate upper surface, wherein the display component and the touch component are folded together to form the touch display panel.

19. The mobile terminal of claim 18, wherein the touch component comprises:
a receive end located at a third location on the flexible substrate upper surface; and
a transmit end located at a fourth location on the flexible substrate upper surface, wherein the receive end and the transmit end are separately folded on to the display component.

20. The mobile terminal of claim 19, wherein the receive end, the transmit end, and the display component are stacked, and wherein layers between the receive end, the transmit end, and the display component are bonded using an optically clear adhesive.

21. The mobile terminal of claim 19, wherein the display component further comprises a display component first side and a display component second side, wherein the receive end is located on the display component first side and the transmit end is located on the display component second side, or wherein the receive end and the transmit end are located side-by-side on the display component first side.

22. The mobile terminal of claim 18, wherein the touch component comprises:
a receive end; and
a transmit end, wherein the receive end and the transmit end are formed at a same location on the flexible substrate upper surface, wherein the receive end and the transmit end are disposed in a stacked manner, and wherein the receive end and the transmit end are folded as on to the display component.

23. The mobile terminal of claim 18, wherein the display component further comprises a display component signal cable, wherein the touch component further comprises a touch component signal cable, wherein the display component signal cable and the touch component signal cable are routed out in an integrated manner and then electrically coupled to an external circuit.

24. The mobile terminal of claim 18, wherein the mobile terminal further comprises:
a polarizer disposed on an upper surface of the touch display panel; and
a cover disposed above the polarizer.

25. The mobile terminal of claim 24, wherein the touch display panel is coupled to an external circuit in a chip on film (COF) manner, or wherein the touch display panel is coupled to the external circuit in a chip on plastic (COP) manner.

26. The mobile terminal of claim 25, wherein the touch display panel is coupled to the external circuit using a COF connector, and a first through hole is disposed at a first location at which the touch display panel is coupled to the COF connector, or wherein the touch display panel is coupled to the external circuit using a COP connector, and a second through hole is disposed at a second location at which the touch display panel is coupled to the COP connector.
